(19) United States
(12) Patent Application Publication
(10) Pub. No.: US 2008/0246129 A1
(43) Pub. Date: Oct. 9, 2008

(54) METHOD OF MANUFACTURING SEMICONDUCTOR DEVICE AND SEMICONDUCTOR DEVICE

(75) Inventor: Akira Oga, Shiga (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/060,484

(22) Filed: Apr. 1, 2008

(30) Foreign Application Priority Data
Apr. 4, 2007 (JP) 2007-097904
Feb. 12, 2008 (JP) 2008-029858

(51) Int. Cl. H01L 21/02; H01L 23/12

(52) U.S. Cl. 257/673; 438/123; 257/E21.002; 257/E23.003

(57) ABSTRACT

The present invention provides a method of manufacturing a semiconductor device in which a plurality of wires are connected to the same electrode on a semiconductor chip, the method making it possible to inhibit an increase in electrode area. First, ball bonding is performed to compressively bond a first ball to an electrode on a semiconductor chip to form a first connection portion. Wedge bonding is then performed on an inner lead. Subsequently, ball bonding is performed to compress a second ball against the first connection portion from immediately above to bond the second ball to form a second connection portion. Wedge bonding is then performed on the inner lead.

### FIELD OF THE INVENTION

The present invention relates to a method of manufacturing a semiconductor device and to the semiconductor device, and in particular, to a packaging technique using a lead frame and a wiring board.

### BACKGROUND OF THE INVENTION

In recent years, as a form of semiconductor device, for example, QFPs (Quad Flat Packages) using lead frames have been widely used. A conventional common QFP semiconductor device will be described with reference to the drawings.

FIG. 17 is a sectional view of the conventional common QFP semiconductor device. FIG. 18 is a partly enlarged diagram of the internal structure of the conventional common QFP semiconductor device.

As shown in FIGS. 17 and 18, in the conventional common QFP semiconductor device, a semiconductor chip 1 with an integrated circuit formed thereon is mounted in a die pad portion 2 of a lead frame. A plurality of leads 4 from the lead frame are radially arranged around the periphery of the die pad portion 2. The tips of inner leads 4a of the radially arranged leads 4 are located opposite to the die pad portion 2. Wires 5 connect electrodes 3 formed on a surface of the semiconductor chip 1 to the respective inner leads 4a. The semiconductor chip 1, the wires 5, and the inner leads 4a are collectively molded with resin by a resin molding member 6. Outer leads 4b of the lead frame continuous with the inner leads 4a are bent like gull wings outside the resin sealing member 6. A die pad support 24 shown in FIG. 18 holds the die pad portion 2 in the lead frame.

Now, description will be given of a method of manufacturing the conventional common QFP semiconductor device.

First, the semiconductor chip 1 is mounted on the die pad portion 2 of the lead frame formed of a metal plate (die bond step).

To allow a plurality of semiconductor devices to be simultaneously or sequentially formed, the lead frame is composed of rectangular patterns corresponding to the semiconductor devices and coupled together with a frame in a lateral direction or a vertical direction on the same plane. Each of the rectangular patterns has a structure in which the die pad portion 2 is located in the center and in which outer ends of the plurality of leads 4 are connected to the frame, with the die pad support 24 holding the die pad portion 2 in the frame.

Then, the electrodes 3 formed on the surface of the semiconductor chip 1 are connected, via the wires 5, to the inner leads 4a arranged around the periphery of the die pad portion 2 (wire bonding step).

Then, the semiconductor chip 1, the die pad portion 2, the wires 5, and the inner leads 4a are collectively molded with resin to form the resin molding member 6 (resin molding step).

Finally, the lead frame is separated into pieces by cutting the outer leads 4b from the frame to a predetermined length. The outer leads 4b are then processed into a predetermined shape.

The above-described steps are executed to obtain the finished semiconductor device.

Furthermore, a currently prevailing wire bonding scheme is an ultrasonic-wave-combined thermocompression bonding scheme. The process of this bonding scheme is as follows.

(1) A ball is formed, by discharge, at the tip of a wire projecting from the tip of a capillary. (2) With the wires heated and subjected to an ultrasonic wave, the capillary is manipulated to press the ball against one connection point to connect one end (ball) of the wire to the connection point (ball bonding) (3) The wire is drawn out of the capillary, while the capillary is moved toward the other connection point. (4) With the wire heated and subjected to an ultrasonic wave, the tip portion of the capillary is manipulated to rub the wire against the other connection point to connect the other end of the wire to the other connection point (wedge bonding).

In general, ball bonding is performed on the electrode side of the semiconductor chip.

For the QFP semiconductor device configured as described above, efforts have been made to increase lead count while reducing lead pitch in order to deal with high-density and highly integrated circuits (see, for example, Shin KOYAMA and Kunihiko NARUSE, “Practical Lesson: VLSI Packaging Technology (II)”, NIKKEI BP, issued on May 31, 1993, p. 165 to p. 170). However, even with the increased lead count and the reduced lead pitch, the external shape and lead count of the QFP semiconductor device are standardized in the industry. Thus, for the QFP semiconductor device, to allow the highly integrated semiconductor chip to be held using a limited number of leads, a power supply electrode, a ground electrode, and the like which can be shared are collectively connected to the same lead. FIGS. 19A and 19B are schematic diagrams showing that the wires 5 connected to the plurality of electrodes 3 are connected to the same inner lead 4a. FIG. 19A shows that the two wires 5 are connected to the same inner lead 4a. FIG. 19B shows that the three wires 5 are connected to the same inner lead 4a.

### DISCLOSURE OF THE INVENTION

As described above, in the conventional QFP semiconductor device, the power supply electrode, ground electrode, and the like which can be shared have been collectively connected to the same lead. On the other hand, circuit scale per semiconductor chip has been sharply increased, resulting in the need for wiring for ensuring stable current supply to the power supply electrode and the ground electrode. In contrast, with improved semiconductor assembly techniques and demands for reduced costs, efforts have been made to reduce the thickness of metal wires typified by Au wires that are wiring material of a semiconductor device. In the conventional QFP semiconductor device, one electrode and one inner leads are connected together using a plurality of wires in order to attain the above-described conflicting objects.

However, at least a specific area is normally required to join the wires together with a sufficient stiffness. Thus, to connect the plurality of wires to the same electrode, it has been conventionally necessary to make the area of electrode large enough to allow the plurality of wires to be subjected to ball bonding. This has been hindering a reduction in chip area.

Furthermore, the plurality of wires may be connected to the same lead on the lead frame or the same front layer wire on a wiring board of a BGA (Ball Grid Array) semiconductor device. Also in this case, the lead or the front layer wire needs to be large enough to allow the plurality of wires to be subjected to ball bonding. This has been hindering a reduction in package area.

In view of these problems, an object of the present invention is to provide a method of manufacturing a semiconductor device in which a plurality of wires are connected to the same electrode on a semiconductor chip, the same lead from a lead frame, or the same front layer wire on a wiring board, the method making it possible to inhibit an increase in electrode area or package area, and to provide the semiconductor device.

To attain the object, a method of manufacturing a semiconductor device according to the present invention includes a first bonding step of forming a ball at a tip of a wire projecting from a wire supply device, performing ball bonding to compressively bond the ball to an electrode on a semiconductor chip or a lead or a wiring member located around a periphery of the semiconductor chip, subsequently moving the wire supply device, and performing wedge bonding on a connection target member, and a second bonding step of forming a ball at a tip of a wire projecting from a wire supply device, performing ball bonding to compress to bond the ball, from immediately above, against a part subjected to the ball bonding in the first bonding step, subsequently moving the wire supply device, and performing wedge bonding on one of the connection target member in the first bonding step and a different connection target member.

Furthermore, in the above-described method of manufacturing a semiconductor device, the second bonding step is executed at least twice to connect a plurality of wires to one of the electrode and the lead or to the wiring member. Moreover, during the repeated second bonding step, at least one wire is connected to the connection target member in the first bonding step by wedge bonding. Alternatively, during the repeated second bonding step, at least two wires are connected by wedge bonding to the same connection target member different from the one in the first bonding step.

The method of manufacturing a semiconductor device further includes a bump forming step of forming a ball at a tip of a wire projecting from a wire supply device and compressively bonding the ball to a part to be subjected to the wedge bonding in the first bonding step and/or the second bonding step, to form a bump, wherein in the first bonding step and/or the second bonding step, the wedge bonding is performed on the bump.

A first semiconductor device according to the present invention includes a semiconductor chip, electrodes provided on the semiconductor chip, a chip mounting portion on which the semiconductor chip is mounted, leads or wiring members arranged around a periphery of the chip mounting portion, wires connecting the electrodes on the semiconductor chip to the leads or the wiring members, and a resin molding member molding at least the semiconductor chip, the chip mounting portion, the wires, and connection portions between the leads or the wiring members and the wires, with resin, wherein connection portions at first ends of some of the plurality of wires are connected to at least one of the electrodes on the semiconductor chip so that the connection portions overlap, and each of the connection portions is shaped such that the wire is drawn out of almost a center of a protruding portion collapsed into a form of a thick coin as is inherent in a ball bonding method.

Furthermore, in the first semiconductor device, at least some of the plurality of wires with the first ends overlappingly connected to the electrodes on the semiconductor chip each have a second end which is shaped like a thin crescent moon or ellipse as is inherent in a wedge bonding method and which is connected to the same lead or wiring member.

Furthermore, the first semiconductor device includes a plurality of the semiconductor chips, and at least some of the plurality of wires with the first ends overlappingly connected to at least one of the electrodes on at least one of the semiconductor chips each have a second end which is shaped like a thin crescent moon or ellipse as is inherent in a wedge bonding method and which is connected to a corresponding electrode on the other semiconductor chip.

Furthermore, the first semiconductor device includes a plurality of the semiconductor chips, some of the plurality of wires with the first ends overlappingly connected to at least one of the electrodes on at least one of the semiconductor chips each have a second end which is shaped like a thin crescent moon or ellipse as is inherent in a wedge bonding method and which is connected to the corresponding electrode on the other semiconductor chip, and some of the plurality of wires each have a second end which is shaped like a thin crescent moon or ellipse as is inherent in the wedge bonding method and which is connected to the lead or the wiring member.

Furthermore, in the first semiconductor device, the chip mounting portion and the lead are constituent members of a lead frame produced by processing a metal plate.

Furthermore, in the first semiconductor device, the chip mounting portion and the wiring member are constituent members of a wiring board.

A second semiconductor device according to the present invention includes a semiconductor chip, electrodes provided on the semiconductor chip, a chip mounting portion on which the semiconductor chip is mounted, leads or wiring members arranged around a periphery of the chip mounting portion, wires connecting the electrodes on the semiconductor chip to the leads or the wiring members, and a resin molding member molding at least the semiconductor chip, the chip mounting portion, the wires, and connection portions between the leads or the wiring members and the wires, with resin, wherein connection portions at first ends of some of the plurality of wires are overlappingly connected to at least one of the leads and the wiring members, and each of the connection portions is shaped such that the wire is drawn out of almost a center of a protruding portion collapsed into a form of a thick coin as is inherent in a ball bonding method.

Furthermore, in the second semiconductor device, some of the plurality of wires with the first ends overlappingly connected to the lead or the wiring member each have a second end which is shaped like a thin crescent moon or ellipse as is inherent in a wedge bonding method and which is connected to the other lead or wiring member, and some of the plurality of wires each have a second end which is shaped like a thin crescent moon or ellipse as is inherent in a wedge bonding method and which is connected to the electrode on the semiconductor chip.

Furthermore, the second semiconductor device includes a plurality of the semiconductor chips, and at least some of the plurality of wires with the first ends overlappingly connected to the lead or the wiring member each have a second end which is shaped like a thin crescent moon or ellipse as is inherent in a wedge bonding method and which is connected to the electrode on each semiconductor chip.

Furthermore, in the second semiconductor device, the chip mounting portion and the lead are constituent members of a lead frame produced by processing a metal plate.

Furthermore, in the second semiconductor device, the chip mounting portion and the wiring member are constituent members of a wiring board.

According to the preferred embodiment of the present invention, at least two wires can be connected to the same electrode on the semiconductor chip without the need to increase the area of the electrode. Thus, in the structure in which the plurality of wires are connected to the same electrode on the semiconductor chip, the area of the electrode can always be minimized regardless of the number of wires connected. This makes it possible to minimize the number and area of electrodes in the entire chip. Consequently, since the electrodes are normally arranged in an outer peripheral portion of the semiconductor chip in one or more lines, the chip size can be reduced by minimizing the number and area of the electrodes. Furthermore, since the plurality of wires can be connected to the same electrode, a current capacity can be stably provided to a power supply electrode and a ground electrode using thinner wires.

As described above, the preferred embodiment can achieve the stable provision of the current capacity to the power supply electrode and ground electrode as well as the reduction in the size of the semiconductor chip. A small-sized, high-quality semiconductor device can be inexpensively provided.

In recent years, in response to a demand for a reduction in the size of equipment, a semiconductor device (package) having a plurality of built-in semiconductor chips has been developed. In some QFP semiconductor devices having such a structure, not only electrodes on each semiconductor chip and leads (inner leads) are connected together via wires but electrodes on different semiconductor chips may also be connected together via wires.

Similarly, for BGA (Ball Grid Array) semiconductor devices using wiring boards, a package having a plurality of built-in semiconductor chips has been developed. In some BGA semiconductor devices having such a structure, not only electrodes on each semiconductor chip and front layer wires (wiring members) on the wiring board are connected together via wires but electrodes on different semiconductor chips may also be connected together via wires.

According to the preferred embodiment of the present invention, some of the plurality of wires connected to the same electrode can be connected to the lead (inner lead) or the wiring member (front layer wire on the wiring board), while some of the plurality of wires can be connected to the electrode on a second semiconductor chip. Thus, the electrode with the plurality of wires connected thereto can be used as a relay electrode between the electrode on the second semiconductor chip and the lead without increasing the chip size. Furthermore, the plurality of wires connected to the same lead (inner lead) or wiring member (front layer wire on the wiring board) can be connected to the respective different electrodes on the corresponding semiconductor chips. Thus, without making the lead or the wiring member large, in other words, without making a package large, the lead or wiring member with the plurality of wires connected thereto can be used as a power source for each semiconductor chip or as a relay lead or relay wire between the electrodes on the different semiconductor chips.

The present invention can thus simplify the wiring in the device and provide the high-quality, compact semiconductor device (semiconductor package) using the high-density and highly integrated semiconductor chip.

As described above, the method of manufacturing a semiconductor device as well as the semiconductor device according to the present invention can inhibit an increase in electrode area or package area in the structure in which the plurality of wires are connected to the same electrode on the semiconductor chip, the same lead from the lead frame, or the same front layer wire on the wiring board. Therefore, the present invention is useful for semiconductor packages such as QFPs and BGAs.

### BRIEF DESCRIPTION OF THE DRAWINGS

FIG. 1 is a sectional view of a semiconductor device according to Embodiment 1 of the present invention;

FIG. 2A is a perspective view illustrating the internal structure of a wire bonding portion of the semiconductor device according to Embodiment 1 of the present invention;

FIG. 2B is a top view illustrating the internal structure of the wire bonding portion of the semiconductor device according to Embodiment 1 of the present invention;

FIG. 2C is a sectional view illustrating the internal structure of the wire bonding portion of the semiconductor device according to Embodiment 1 of the present invention;

FIG. 3 is a sectional view illustrating a wire bonding process for the semiconductor device according to Embodiment 1 of the present invention;

FIG. 4 is a sectional view illustrating another example 1 of the wire bonding process for the semiconductor device according to Embodiment 1 of the present invention;

FIG. 5 is a sectional view illustrating another example 2 of the wire bonding process for the semiconductor device according to Embodiment 1 of the present invention;

FIG. 6 is a sectional view illustrating another example 3 of the wire bonding process for the semiconductor device according to Embodiment 1 of the present invention;

FIG. 7 is a sectional view illustrating the internal structure of a wire bonding portion of a semiconductor device according to Embodiment 2 of the present invention;

FIG. 8 is a sectional view illustrating the internal structure of a wire bonding portion of a semiconductor device according to Embodiment 3 of the present invention;

FIG. 9A is a top view illustrating the internal structure of a wire bonding portion of a semiconductor device according to Embodiment 4 of the present invention;

FIG. 9B is a sectional view illustrating the internal structure of the wire bonding portion of the semiconductor device according to Embodiment 4 of the present invention;

FIG. 10A is a top view illustrating another example of the internal structure of the wire bonding portion of the semiconductor device according to Embodiment 4 of the present invention;

FIG. 10B is a sectional view illustrating another example of the internal structure of the wire bonding portion of the semiconductor device according to Embodiment 4 of the present invention;

FIG. 11 is a sectional view of a semiconductor device according to Embodiment 5 of the present invention;

FIG. 12 is a sectional view of a semiconductor device according to Embodiment 6 of the present invention;

FIG. 13A is a top view illustrating the internal structure of a wire bonding portion of the semiconductor device according to Embodiment 6 of the present invention;

FIG. 13B is a sectional view illustrating the internal structure of the wire bonding portion of the semiconductor device according to Embodiment 6 of the present invention;

FIG. 14 is a sectional view illustrating a wire bonding process for the semiconductor device according to Embodiment 6 of the present invention;

FIG. 15 is a sectional view of a semiconductor device according to Embodiment 7 of the present invention;

FIG. 16A is a top view illustrating the internal structure of a wire bonding portion of the semiconductor device according to Embodiment 7 of the present invention;

FIG. 16B is a sectional view illustrating the internal structure of the wire bonding portion of the semiconductor device according to Embodiment 7 of the present invention;

FIG. 17 is a sectional view of a conventional common QFP semiconductor device;

FIG. 18 is a partly enlarged view of the internal structure of the conventional common QFP semiconductor device;

FIG. 19A is a schematic view of the conventional common QFP semiconductor device in which each wire connected to respective two electrodes is connected to the same inner lead; and

FIG. 19B is a schematic view of the conventional common QFP semiconductor device in which each wire connected to respective three electrodes is connected to the same inner lead.

### DESCRIPTION OF THE EMBODIMENT(S)

### Embodiment 1

Embodiment 1 of the present invention will be described below with reference to the drawings.

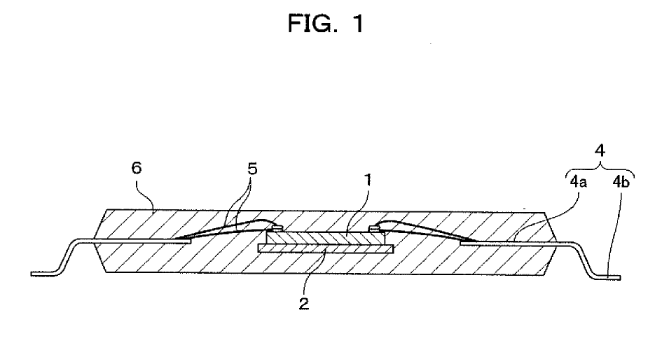

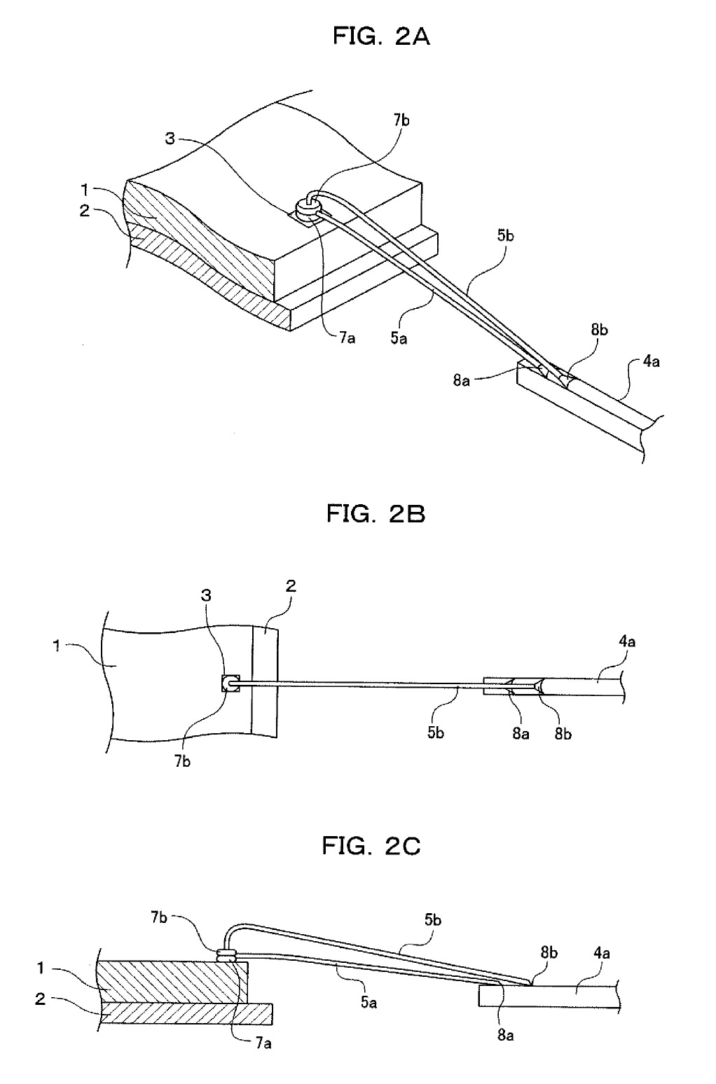

FIG. 1 is a sectional view of a semiconductor device according to Embodiment 1 of the present invention. FIG. 2A is a perspective view illustrating the internal structure of a wire bonding portion of the semiconductor device according to Embodiment 1 of the present invention. FIG. 2B is a top view illustrating the internal structure of the wire bonding portion of the semiconductor device according to Embodiment 1 of the present invention. FIG. 2C is a sectional view illustrating the internal structure of the wire bonding portion of the semiconductor device according to Embodiment 1 of the present invention. In the description below, the same members are denoted by the same reference numerals, and the description of these members is appropriately omitted.

The semiconductor device is of a QFP type. As shown in FIG. 1, in the semiconductor device, a semiconductor chip 1 with an integrated circuit formed thereon is mounted on a die pad portion (chip mounting portion) 2 of a lead frame. Leads 4 from the lead frame are radially arranged around the periphery of the die pad portion 2. The tips of inner leads 4a of the radially arranged leads 4 are located opposite to the die pad portion 2. Wires 5 connect respective electrodes 3 formed on a surface of the semiconductor chip 1 to the corresponding inner leads 4a. A resin molding member 6 collectively molds the semiconductor chip 1, the die pad portion 2, the wires 5, and the inner leads 4a (wire connecting portions of the leads 4) with resin. Outer leads 4b of the lead frame continuous with the inner leads 4a are bent like gull wings outside the resin molding member 6.

The semiconductor device is different from the conventional one in the following two respects. First, as shown in FIGS. 2A to 2C, first ends of two wires 5a and 5b are overlappingly connected to at least one of the electrodes 3 on the semiconductor chip 1. The connection portion is shaped such that the wire is drawn out of almost the center of a protruding portion collapsed into a thick coin form as is inherent in a ball bonding method. Second, second ends of the two wires 5a and 5b are shaped like a thin crescent moon or ellipse as is inherent in a wedge bonding method and is connected to the same inner lead 4a.

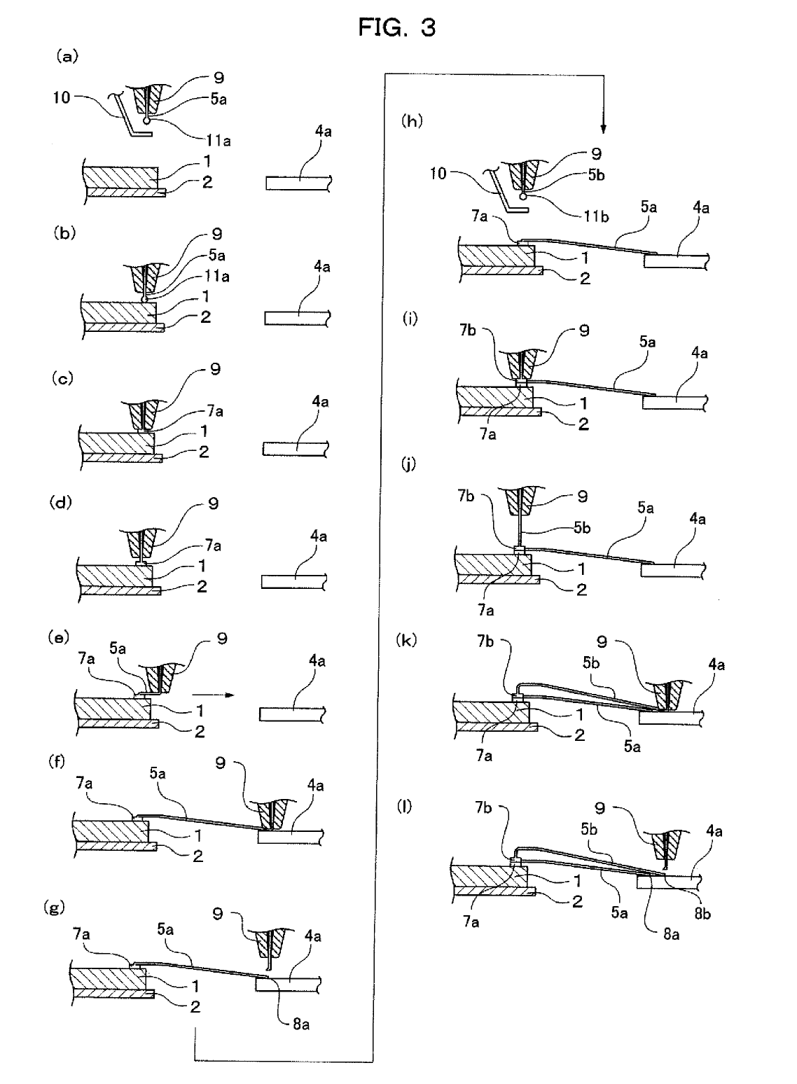

Now, with reference to a sectional view of a process in FIG. 3, description will be given of a method of connecting the two wires to the same electrode.

First, as shown in FIG. 3A, discharge is caused between a torch 10 and the tip of a wire 5a projecting from the tip of a capillary 9 that is a wire supply device. Spark thus occurs to form a ball 11a.

Then, as shown in FIGS. 3B to 3D, the ball 11a is compressively bonded to the electrode on the semiconductor chip 1 (ball bonding) to form a ball bonding-side connection portion 7a.

Then, as shown in FIGS. 3E to 3G, the wire 5a is bent in a horizontal direction and drawn out. The capillary 9 is moved so that the wire 5a is routed along a predetermined track. The wire 5a is rubbed against the inner lead 4a, which is a connection target member (wedge bonding). Thus, a wedge bonding-side connection portion 8a is formed.

After the above-described first bonding step, the second bonding step is executed.

First, as shown in FIG. 3H, discharge is caused between the torch 10 and the tip of a wire 5b projecting from the tip of the capillary 9. Spark thus occurs to form a ball 11b.

Then, as shown in FIG. 3I, the ball 11b is compressed to be bonded against the connection portion 7a (part subjected to the ball bonding in the first bonding step) from immediately above (ball bonding). A ball bonding-side connection portion 7b is thus formed.

Then, as shown in FIGS. 3J to 3L, the wire 5b is drawn out in a vertical direction and bent. The capillary 9 is moved so that the wire 5b is routed along a predetermined track. The wire 5b is rubbed against the inner lead 4a, which is a connection target member (wedge bonding). Thus, a wedge bonding-side connection portion 5b is formed.

The connection target member in the first bonding step and second bonding step is the same inner lead 4a.

The first and second bonding steps are executed as described above to allow the first ends of the two wires to be overlappingly connected to the same electrode by means of the ball bonding method.

The wire used in a wire bonding step is generally composed of metal such as gold or copper and has a diameter φ of 15 to 40 μm. The diameter of the ball formed at the first end of the wire by the ball bonding method is about 1.5 to 4 times as large as that of the wire. When joined to the connection point, the ball is collapsed by the tip portion of the capillary such that the thickness of the ball becomes 5 to 60 μm. As a result, the ball bonding-side connection portion is shaped such that the wire is drawn out of almost the center of the protruding portion collapsed into a thick coin form.

On the other hand, the second end of the wire is collapsed by the peripheral portion of the tip of the capillary so as to be rubbed against the connection portion. The wedge bonding-side connection portion is thus shaped like a thin crescent moon or ellipse.

For example, as shown in FIG. 3G, a part of the wire 5a is present above the ball bonding-side connection portion 7a. Thus, to prevent the misaligned connection of the part of the wire 5a and the ball 11b compressively bonded to the part of the wire 5a, the capillary 9 needs to reliably hold the ball 11b.

In this connection, a method described below makes it possible to easily prevent misaligned connections.

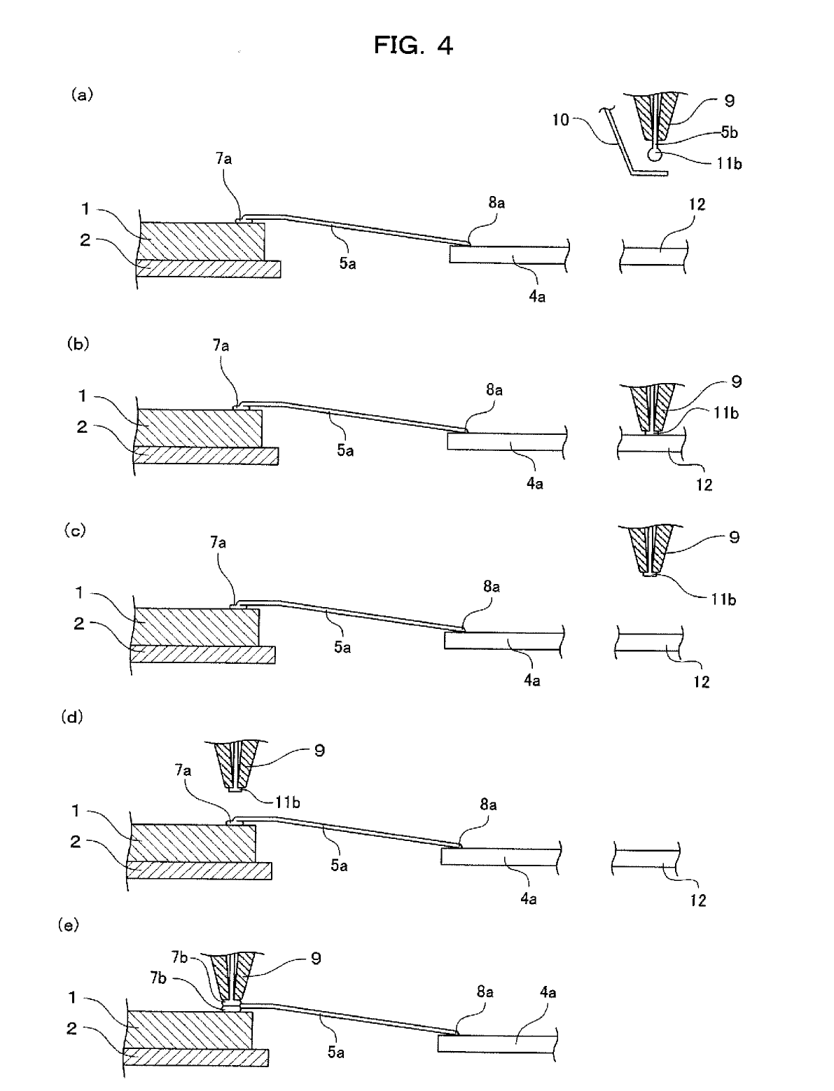

FIG. 4 is a sectional view illustrating a method of preventing possible misaligned connection when the plurality of wires are overlappingly connected to the same electrode.

First, after the first bonding step, as shown in FIG. 4A, discharge is caused between the torch 10 and the tip of the wire 5b projecting from the tip of the capillary 9. Spark thus occurs to form the ball 11b.

Then, as shown in FIG. 4B, the ball 11b is pressed against a flat portion 12 to form a flat surface on a bottom surface of the ball 11b.

Then, as shown in FIGS. 4C and 4D, the ball 11b is compressed to be bonded against the connection portion 7a from immediately above. The ball bonding-side connection portion 7b is thus formed.

Thus, during the second bonding step, the ball 11b is formed at the tip of the wire 5b projecting from the capillary 9. Then, the ball 11b is pressed against the flat portion 12 to form the flat surface on the bottom surface of the ball 11b. The ball 11b with the flat surface formed thereon is bonded to the connection portion.

With this method, the bottom surface of the ball 11b is made flat, making it possible to prevent contact misalignment when the wire 5a present above the connection portion 7a comes into contact with the ball 11b. Thus, reliable junction can be achieved.

The flat portion 12 may be, for example, a flat surface constituting a part of the lead frame or a part of a wire bond facility. Furthermore, if the present invention is applied to a BGA semiconductor device, the flat portion 12 may be a flat surface of a part of the wiring board as described below.

Alternatively, a method described below may be used to prevent possible misaligned connection.

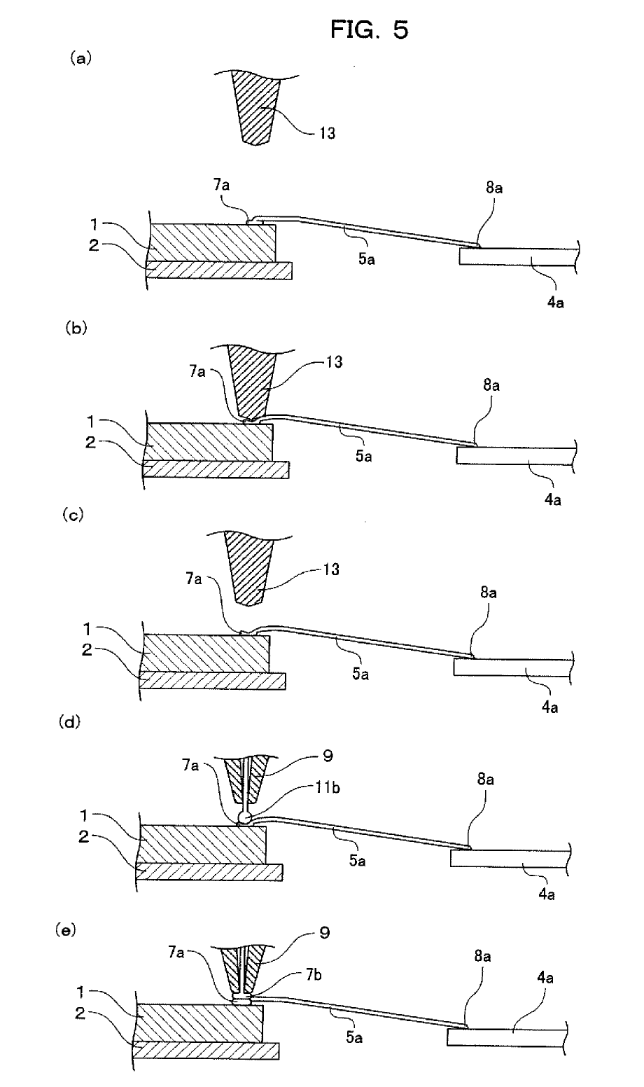

As shown in FIGS. 5A to 5C, after the first bonding step, a pressurizing tool 13 with a tip shaped like a conical protrusion is pressed against the connection portion 7a from immediately above to collapse the connection portion 7a.

Then, as shown in FIGS. 5D and 5E, the ball 11(b) is compressed against the collapsed connection portion 7a from immediately above to form the ball bonding-side connection portion 7b.

A conical recess is formed at the top of the connection portion 7a against which the tip portion of the pressurizing tool 13 has been pressed. The ball 11b is reliably aligned with the center of the recess. This enables a more reliable junction.

The conical tip portion of the pressurizing tool 13 is desirably set to have an obtuse angle of aperture of 120 to 170°.

Thus, in the second bonding step, the pressurizing tool is pressed against the part (connection portion 7a) to be subjected to ball bonding from immediately above, to collapse the part (connection portion 7a). The collapsed part is then subjected to ball bonding.

Alternatively, a method described below may be used to prevent possible misaligned connection. This method is the same as the above-described one except that the tip of the pressurizing tool is shaped like a spherical protrusion.

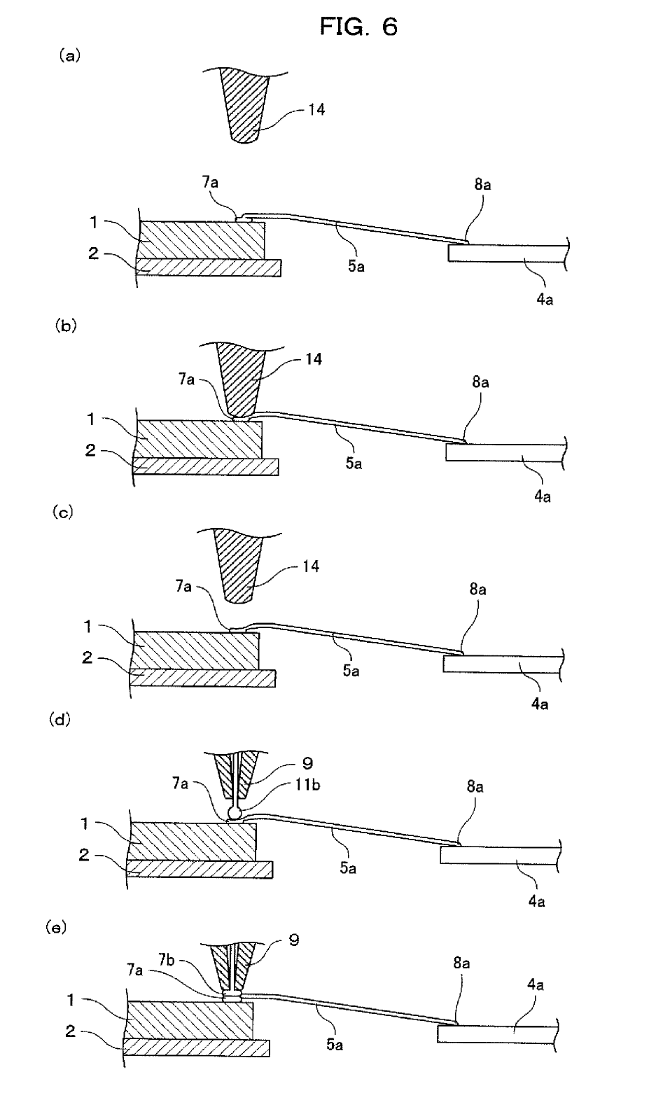

As shown in FIGS. 6A to 6C, after the first bonding step, a pressurizing tool 14 with a tip shaped like a spherical protrusion is pressed against the connection portion 7a from immediately above to collapse the connection portion 7a.

Then, as shown in FIGS. 6D and 6E, the ball 11(b) is compressed against the collapsed connection portion 7a from immediately above to form the ball bonding-side connection portion 7b.

A spherical recess is formed at the top of the connection portion 7a against which the tip portion of the pressurizing tool 13 has been pressed. When the ball 11b is compressively bonded to the connection portion 7a, a central part of the recess first comes into point contact with the ball 11b. This enables reliable alignment. Furthermore, the spherical recess enables reliable junction without creating any void.

The radius of the spherical surface at the tip portion of the pressurizing tool 14 is desirably set within the range of 1.5 to 5 times as large as that of the ball 11b.

The above-described method can prevent possible contact misalignment connection when the connection portion formed by the ball bonding method is further connected to the first end of the different wire by the ball bonding method.

In Embodiment 1, the second ends of the plurality of wires connected to the same electrode are connected to the same inner lead. However, the wires may be connected to the respective different inner leads.

### Embodiment 2

Now, Embodiment 2 of the present invention will be described with reference to the drawings. FIG. 7 is a sectional view illustrating the internal structure of a wire bonding portion of a semiconductor device according to Embodiment 2 of the present invention. However, the same members as those described above in Embodiment 1 are denoted by the same reference numerals, and the description of these members is omitted.

This semiconductor device is different from that in Embodiment 1, described above, in that first ends of three wires are overlappingly connected to at least one electrode on a semiconductor chip by means of a ball bonding method, with second ends of the three wires connected to the same inner lead at different positions by means of a wedge bonding method.

That is, as shown in FIG. 7, ball bonding-side connection portions 7a to 7c of wires 5a to 5c are overlappingly formed on the same electrode on the semiconductor chip 1. Wedge bonding-side connection portions 8a to 8c of the wires 5a to 5c are formed on the same inner lead 4a at different positions. This connection can be made by repeating the second bonding step twice, described in Embodiment 1.

This configuration allows current capacity to be adjusted as required, making it possible to provide a farther small, high-quality and low cost semiconductor device.

In the description of Embodiment 2, the three wires are connected to the same electrode. However, at least three wires can be connected to the same electrode by repeating the second bonding step at least twice.

### Embodiment 3

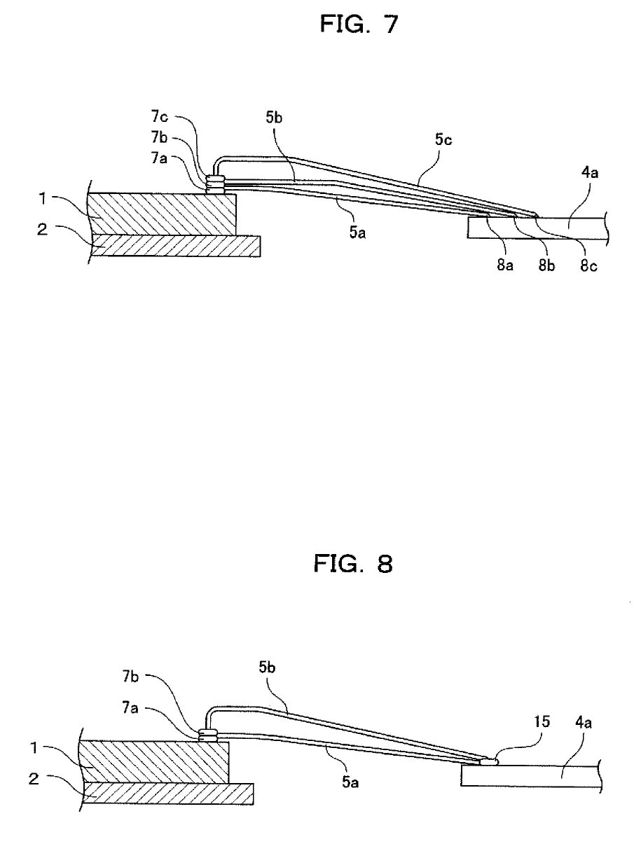

Now, Embodiment 3 of the present invention will be described with reference to the drawings. FIG. 8 is a sectional view illustrating the internal structure of a wire bonding portion of a semiconductor device according to Embodiment 3 of the present invention. However, the same members as those described above in Embodiments 1 and 2 are denoted by the same reference numerals, and the description of these members is omitted.

This semiconductor device is different from that in Embodiment 1, described above, in that first ends of two wires are overlappingly connected to at least one electrode on a semiconductor chip by means of a ball bonding method, with second ends of the two wires connected to the same inner lead at the same connection point via a bump by means of a wedge bonding method.

That is, as shown in FIG. 8, a bump 15 is formed on the wedge bonding-side connection portion of the wire 5a. The connection portion of the wedge bonding-side of the wire 5b is formed on the bump 15.

The bump 15 can be formed by forming a ball at the tip of the wire projecting from a capillary and compressively bonding the ball to a part to be subjected to wedge bonding during the second bonding step.

Thus, the wedge bonding-side connection portion of the wire 5b can be formed on the bump 15 by executing the bump forming step before the wedge bonding of the wire 5b and performing the wedge bonding on the bump 15 during the second bonding step.

According to Embodiment 3, on both the ball banding side and the wedge bonding side, a plurality of wires can be connected to the area to which only one wire can be conventionally connected. This enables a reduction in the size of the semiconductor chip as well as that of a lead frame. Furthermore, the degree of freedom of wiring is improved. Embodiment 3 thus contributes significantly to miniaturizing the semiconductor device.

Furthermore, the connection portions formed by the wedge bonding method are each shaped like a thin crescent moon or ellipse as described above. Thus, to bond the connection portions together so that the connection portions vertically overlap, it is important to stabilize the connection condition of each wire. In contrast, when the bump is formed and wedge bonding is performed on the bump as in the case of the present embodiment, the wire connection portions stacked by the wedge bonding are firmly joined together via the bump. The reliability of the junction can thus be improved.

In the description of Embodiment 3, the two wedge bonding-side connection portions are stacked. However, at least three wedge bonding-side connection portions can be stacked by repeating the above-described bump forming step to form the bump on the previously formed connection portion.

### Embodiment 4

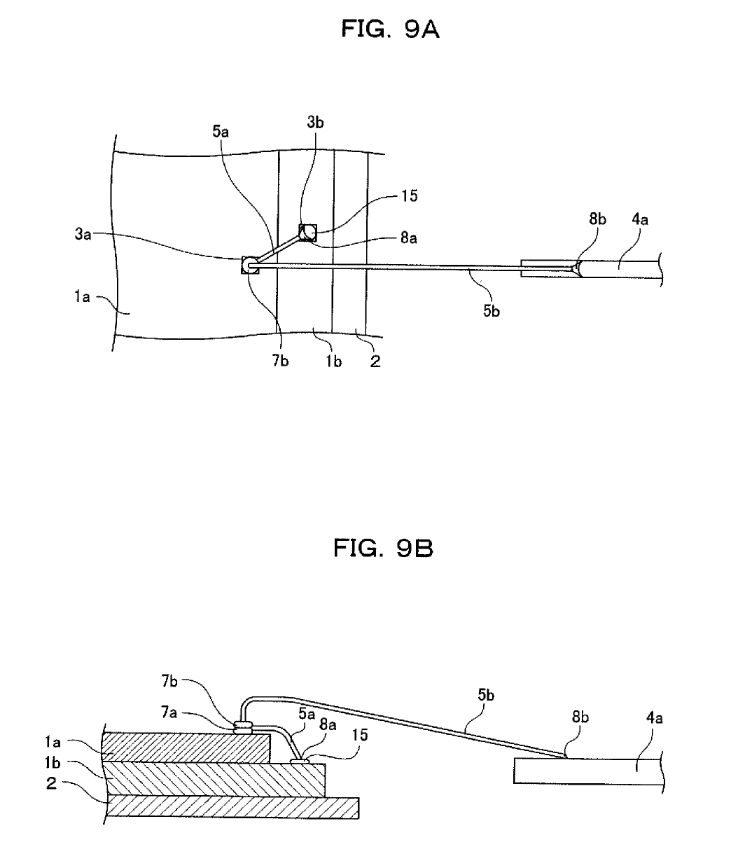

Now, Embodiment 4 of the present invention will be described with reference to the drawings. FIG. 9A is a top view illustrating the internal structure of a wire bonding portion of a semiconductor device according to Embodiment 4 of the present invention. FIG. 9B is a sectional view illustrating the internal structure of the wire bonding portion of the semiconductor device according to Embodiment 4 of the present invention. However, the same members as those described above in Embodiments 1 to 3 are denoted by the same reference numerals, and the description of these members is omitted.

This semiconductor device is different from Embodiments 1 to 3, described above, in that two semiconductor chips stacked in a vertical direction are mounted in a die pad portion and in that a plurality of wires connected to the same electrode are connected to respective different connection target members.

That is, as shown in FIGS. 9A and 9B, first ends of two wires 5a and 5b are overlappingly connected to the same electrode 3a on an upper semiconductor chip 1a by means of a ball bonding method. A second end of the wire 5a is connected to an electrode 3b on a lower semiconductor chip 1b by a wedge bonding method. A second end of the wire 5b is connected to an inner lead 4a by means of the wedge bonding method.

In this case, before the wire 5a is subjected to wedge bonding, a bump 15 is formed on the part (electrode 3b) of the wire 5a which is to be subjected to the wedge bonding. A wedge bonding-side connection portion 8a of the wire 5a is formed on the bump 15. The bump is formed by forming a ball at the tip of the wire projecting from a capillary and compressively bonding the ball to the part (electrode 3b) to be subjected to wedge bonding during the first bonding step (bump forming step).

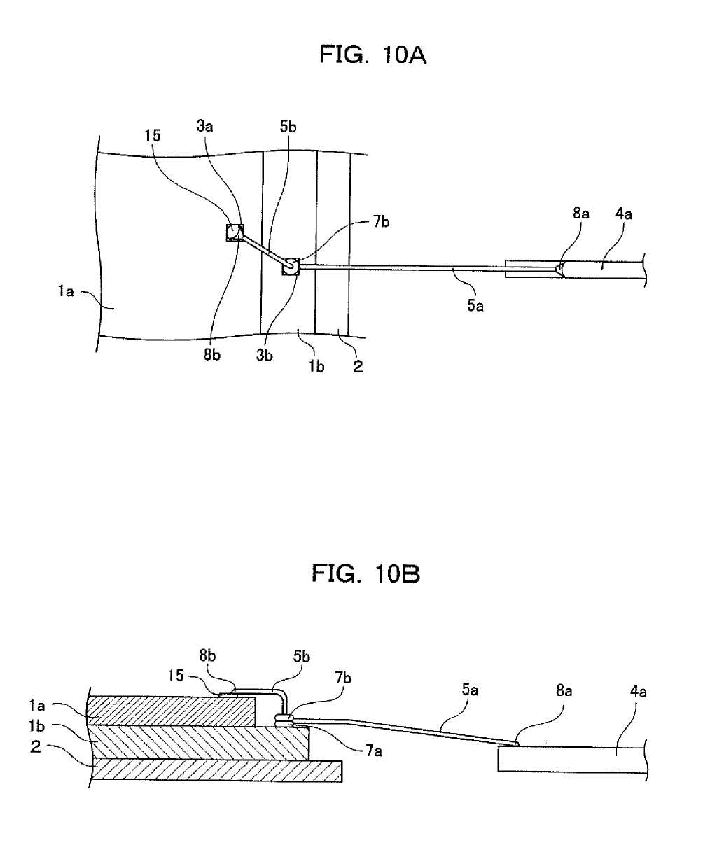

Alternatively, as shown in FIGS. 10A and 10B, the plurality of wires may be connected to the same electrode 3b on the lower semiconductor chip 1b. FIG. 10A is a top view illustrating another example of the internal structure of the wire bonding portion of the semiconductor device according to Embodiment 4 of the present invention. FIG. 10B is a sectional view illustrating another example of the internal structure of the wire bonding portion of the semiconductor device according to Embodiment 4 of the present invention.

As shown in FIGS. 10A and 10B, the first ends of the two wires 5a and 5b are overlappingly connected to the same electrode 3b on the lower semiconductor chip 1b by means of the ball bonding method. The second end of the wire 5a is connected to the inner lead 4a by means of the wedge bonding method. The second end of the wire 5b is connected to the electrode 3a on the upper semiconductor chip 1a by the wedge bonding method.

In this case, before the wire 5b is subjected to wedge bonding, the bump 15 is formed on the part (electrode 3a) of the wire 5b which is to be subjected to the wedge bonding. A wedge bonding-side connection portion 8b of the wire 5b is formed on the bump 15. The bump is formed by forming a ball at the tip of the wire projecting from the capillary and compressively bonding the ball to the part (electrode 3a) to be subjected to wedge bonding during the second bonding step (bump forming step).

In the above-described embodiment, the first ends of the two wires are overlappingly connected to the same electrode on the semiconductor chip. However, of course, the first ends of at least three wires may be overlappingly connected to the same electrode. Furthermore, in the above-described embodiment, one of the two wires connected to the same electrode is connected to the electrode on the other semiconductor chip, with the other wire connected to the inner lead. However, the present invention is not limited to this connection form. The wedge bonding-side connection target member of the plurality of wires connected to the same electrode may be the same electrode on the other semiconductor chip, different electrodes on the other semiconductor chip, the same inner lead, or different inner leads. Furthermore, if the same wedge bonding-side connection target member is used, the wedge bonding-side connection portions may be overlappingly connected to the same connection point by forming the bump as described in Embodiment 3.

In the above description, the two semiconductor chips are arranged in the vertical direction. However, even when the two semiconductor chips may be arranged in parallel on the same plane, at least three semiconductor chips may be arranged in the vertical direction or in parallel on the same plane, or the parallel arrangement and the vertical arrangement may be combined together, the plurality of wires connected to the same electrode can be connected to the respective different connection target members or the same connection target member.

According to Embodiment 4, the thickness of the wires can be reduced while ensuring a stable current capacity for the power supply electrode and the ground electrode. This enables a reduction in the number and area of the electrodes, in the number of leads, in the area of the wire connection portion of the lead, in relay leads for inter-chip connections, and the like. Thus, Embodiment 4 contributes to the reduced size of the semiconductor chip and the increased degree of integration for the semiconductor chip as well as the reduced size of the semiconductor device and the increased degree of integration for the semiconductor device. As a result, the high-quality, inexpensive semiconductor device can be provided.

### Embodiment 5

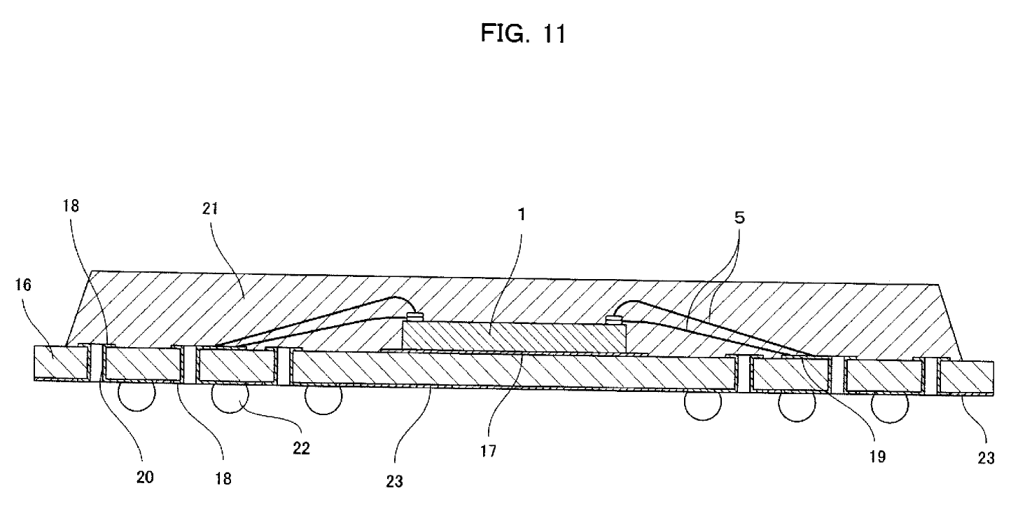

Now, Embodiment 5 of the present invention will be described with reference to the drawings. FIG. 11 is a sectional view of a semiconductor device according to Embodiment 5 of the present invention. However, the same members as those described above in Embodiments 1 to 4 are denoted by the same reference numerals, and the description of these members is omitted.

This semiconductor device is of a BGA type. As shown in FIG. 11, the BGA semiconductor device is made up of a resin base material and uses a wiring board 16 having metal wiring 18 on at least a major surface and a bottom surface located opposite to the major surface.

As shown in FIG. 11, in the semiconductor device, a semiconductor chip 1 with an integrated circuit formed thereon is mounted in a die pad portion (chip mounting portion) 17 of the wiring board 16. The die pad portion 17 is made up of the metal wiring 18 on the major surface, which corresponds to front layer wiring. Connection pads 19 are radially arranged around the periphery of the die pad portion 17. Tips of the connection pads 19 are located opposite to the die pad portion 17. The connection pads 19 are made up of the metal wiring (wiring material) 18 on the major surface, which corresponds to the front layer wiring. Wires 5 connect electrodes 3, formed on the surface of the semiconductor chip 1, to the connection pads 19. The metal wiring 18 on the major surface side is electrically connected to the metal wiring 18 on the bottom surface via through-vias 20. Furthermore, a resin molding member 21 molds at least the semiconductor chip 1, the die pad portion 17, the wires 5, and the connection portions (connection pad 19) with the wires 5 in the front layer wire (wiring member) with resin. Solder balls 22 are formed on the bottom surface. The solder balls 22 are electrically connected to the metal wiring 18 on the bottom surface side. Resists 23 are formed in areas on the bottom surface in which the metal wiring 18 is not formed.

As is the case with Embodiment 1, described above, this semiconductor device is different from the conventional one in that first ends of the two wires 5 are overlappingly connected to at least one electrode 3 on the semiconductor chip 1 by means of a ball bonding method and in that second ends of the two wires 5 are connected to the same connection pad 19 (wiring member) by means of a wedge bonding method.

Furthermore, this semiconductor device is different from Embodiments 1 to 4, described above, only in that the wiring material, one of the constituent materials of the semiconductor device, is not a lead frame but the wiring board. Thus, a semiconductor device having a structure similar to that of the semiconductor device according to Embodiments 1 to 4 can be implemented by replacing the inner lead in Embodiments 1 to 4, described above, with a connection land (wiring member).

That is, in the BGA semiconductor device, the first ends of the two wires can be overlappingly connected to the same electrode as is the case with Embodiment 1 (see FIG. 3). In this case, a flat surface may be formed on the bottom surface of the hall as is the case with Embodiment 1 (see FIG. 4). In the second bonding step, a pressurizing tool may be pressed, from immediately above, against the part to be subjected to ball bonding, to collapse the part (see FIGS. 5 and 6).

Furthermore, in the BGA semiconductor device, as is the case with Embodiment 2, the first ends of the plurality of wires can be overlappingly connected to at least one electrode on the semiconductor chip by means of the ball bonding method (see FIG. 7).

Furthermore, in the BGA semiconductor device, as is the case with Embodiment 3, the second ends of the plurality of wires connected to at least one electrode on the semiconductor chip can be overlappingly connected to the same connection pad (wiring member) at the same connection point via a bump by means of the wedge bonding method (see FIG. 8).

Furthermore, in the BGA semiconductor device having a plurality of the semiconductor chips built in the package, as is the case with Embodiment 4, the plurality of wires connected to the same electrode can be connected to the respective different connection target members or the same connection target member (see FIGS. 9A, 9B, 10A, and 10B).

Therefore, the present embodiment can provide the inexpensive semiconductor device using the wiring board typified by the BGA as a wiring material and also using the highly integrated, high-quality semiconductor chip.

### Embodiment 6

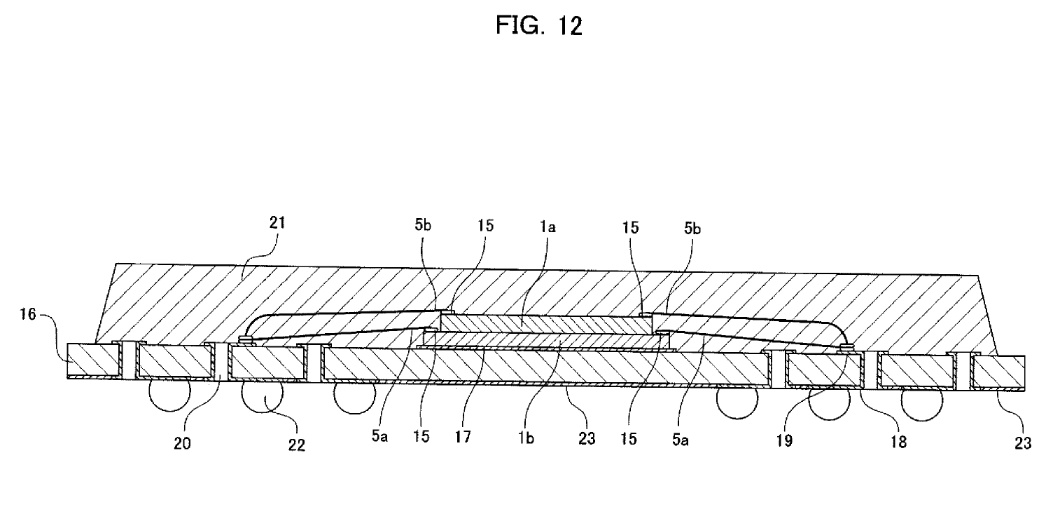

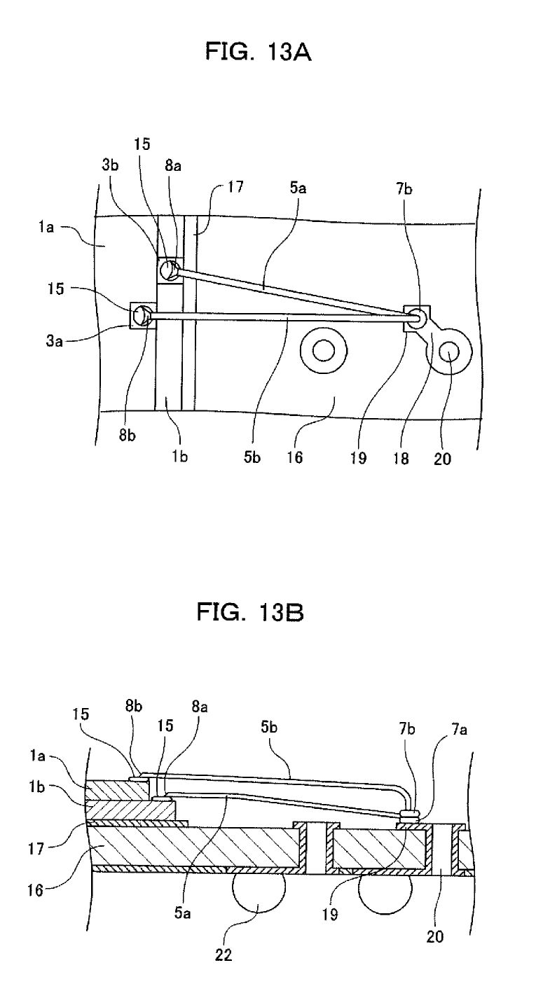

Now, Embodiment 6 of the present invention will be described with reference to the drawings. FIG. 12 is a sectional view of a semiconductor device according to Embodiment 6 of the present invention. FIG. 13A is a top view illustrating the internal structure of a wire bonding portion of the semiconductor device according to Embodiment 6 of the present invention. FIG. 13B is a sectional view illustrating the internal structure of the wire bonding portion of the semiconductor device according to Embodiment 6 of the present invention. However, the same members as those described above in Embodiments 1 to 5 are denoted by the same reference numerals, and the description of these members is omitted.

This semiconductor device is different from Embodiment 5, described above, in that first ends of two wires are overlappingly connected to the same connection pad (wiring member) on a wiring board by means of a ball bonding method and in that the wires are connected to electrodes on respective different semiconductor chips.

That is, in Embodiment 6, as shown in FIGS. 12, 13A, and 13B, connection portions at first ends of two wires 5a and 5b are overlappingly connected to the same connection pad 19. Each of the connection portions is shaped such that the wire is drawn out of almost the center of a protrusion collapsed into a thick coin as is inherent in the ball bonding method. Furthermore, the two semiconductor chips 1a and 1b stacked in a vertical direction are mounted in a die pad portion (chip mounting portion) 17. A second end of the wire 5a is shaped like a thin crescent moon or ellipse as is inherent in a wedge bonding method and is connected to an electrode 3b on a lower semiconductor chip 1b. A second end of the wire 5b is shaped like a thin crescent moon or ellipse as is inherent in the wedge bonding method and is connected to an electrode 3a on an upper semiconductor chip 1a.

In this case, before the wire 5a is subjected to wedge bonding, a bump 15 is formed on the part (electrode 3b) of the wire 5a which is to be subjected to the wedge bonding. A wedge bonding-side connection portion 8a of the wire 5a is formed on the bump 15. The bump is formed by forming a ball at the tip of the wire projecting from a capillary and compressively bonding the ball to the part (electrode 3b) to be subjected to the wedge bonding in the first bonding step (bump forming step).

Moreover, before the wedge bonding of the wire 5b, the bump 15 is formed on the part (electrode 3a) of the wire 5b which is to be subjected to the wedge bonding. A wedge bonding-side connection portion 8b of the wire 5b is formed on the bump 15. The bump is formed by forming a ball at the tip of the wire projecting from the capillary and compressively bonding the ball to the part (electrode 3a) to be subjected to the wedge bonding in the second bonding step (bump forming step).

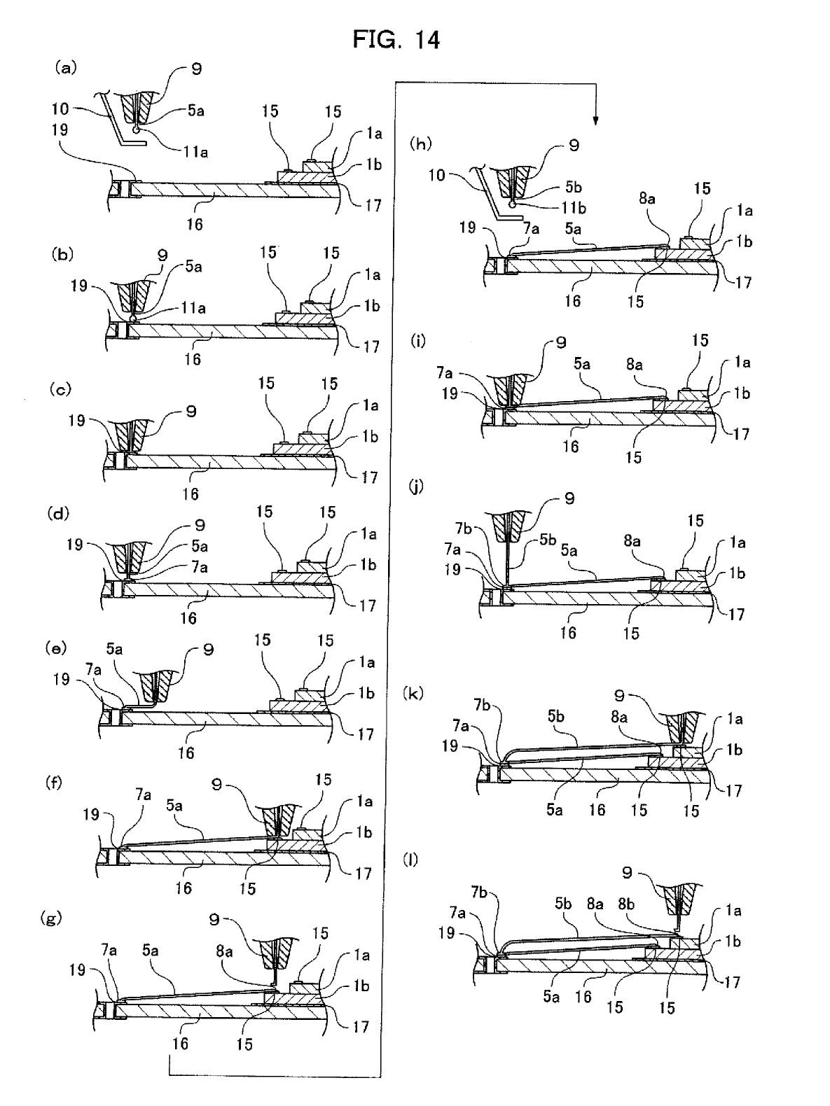

Now, description will be given of a method of connecting the two wires to the same connection pad, with reference to a sectional view in FIG. 14 showing the process. In the description below, the bump 15 is formed in advance on each of the electrodes 3a and 3b on the semiconductor chips 1a and 1b, the connection target members in the bonding steps. A land 15 may be formed at any time before wedge bonding is performed during each bonding process.

First, as shown in FIG. 14A, discharge is caused between a torch 10 and the tip of the wire sa projecting from the tip of a capillary 9. Spark thus occurs to form a ball 11a.

Then, as shown in FIGS. 14B to 14D, the ball 11a is compressively bonded to the connection pad 19 on a wiring board 16 (ball bonding) to form a ball bonding-side connection portion 7a.

Then, as shown in FIGS. 14E to 14G, the wire 5a is bent in a horizontal direction and drawn out. The capillary 9 is moved so that the wire 5a is routed along a predetermined track. The wire 5a is rubbed against the land 15, the connection target member, formed on the electrode 3b on the semiconductor chip 1b (wedge bonding). Thus, the wedge bonding-side connection portion 8a is formed.

After the above-described first bonding step, the second bonding step is executed.

First, as shown in FIG. 14H, discharge is caused between the torch 10 and the tip of the wire 5b projecting from the tip of the capillary 9. Spark thus occurs to form a ball 11b.

Then, as shown in FIG. 14I, the ball 11b is compressed against the connection portion 7a (part subjected to the ball bonding in the first bonding step) from immediately above and thus bonded to the connection portion 7a (ball bonding). A ball bonding-side connection portion 7b is thus formed.

Then, as shown in FIGS. 14J to 14L, the wire 5b is drawn out in the vertical direction and bent. The capillary 9 is moved so that the wire 5b is routed along a predetermined track. The wire 5b is rubbed against the land 15, the connection target member, formed on the electrode 3a on the semiconductor chip 1a (wedge bonding). Thus, the wedge bonding-side connection portion 8b is formed.

Thus executing the first and second bonding steps allows the first ends of the two wires to be overlappingly connected to the same connection pad (wiring member) by means of the ball bonding method. When the first ends of the plurality of wires are overlappingly connected together, a flat surface may be formed on the bottom surface of the ball as is the case with Embodiment 1 (see FIG. 4). In the second bonding step, a pressurizing tool may be used to press, from immediately above, the part to be subjected to ball bonding, to collapse the part (see FIGS. 5 and 6).

As described above, this semiconductor device is different from the conventional one in that the first ends of the plurality of the wires are overlappingly connected to the same connection pad (wiring member) on the wiring board by means of the ball bonding method and in that the plurality of wires connected to the same connection pad are connected to the respective different connection target members.

As is the case with Embodiment 2, the first ends of the plurality of wires may be overlappingly connected to the same connection pad by means of the ball bonding method (see FIG. 7).

Furthermore, as is the case with Embodiment 3, the second ends of the plurality of wires connected to the same connection pad may be overlappingly connected to the same electrode on the same semiconductor chip or to the other connection pad on the wiring board via the bump by means of the wedge bonding method (see FIG. 8).

Embodiment 6 can provide the high-quality, inexpensive semiconductor device which uses the wiring board typified by the BGA as a wiring material and which enables an easy reduction in the area of the wire connection portion of the wiring board.

### Embodiment 7

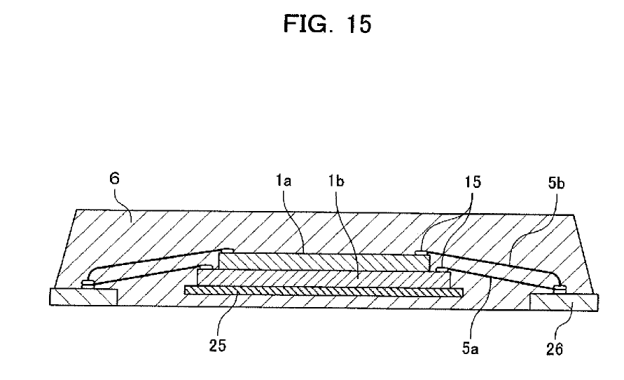

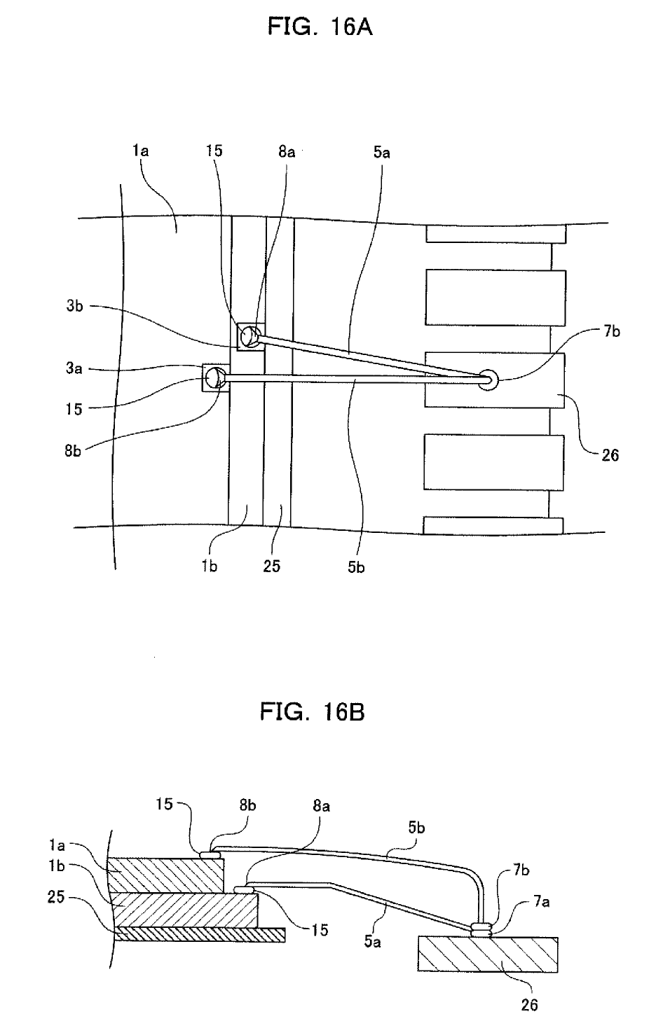

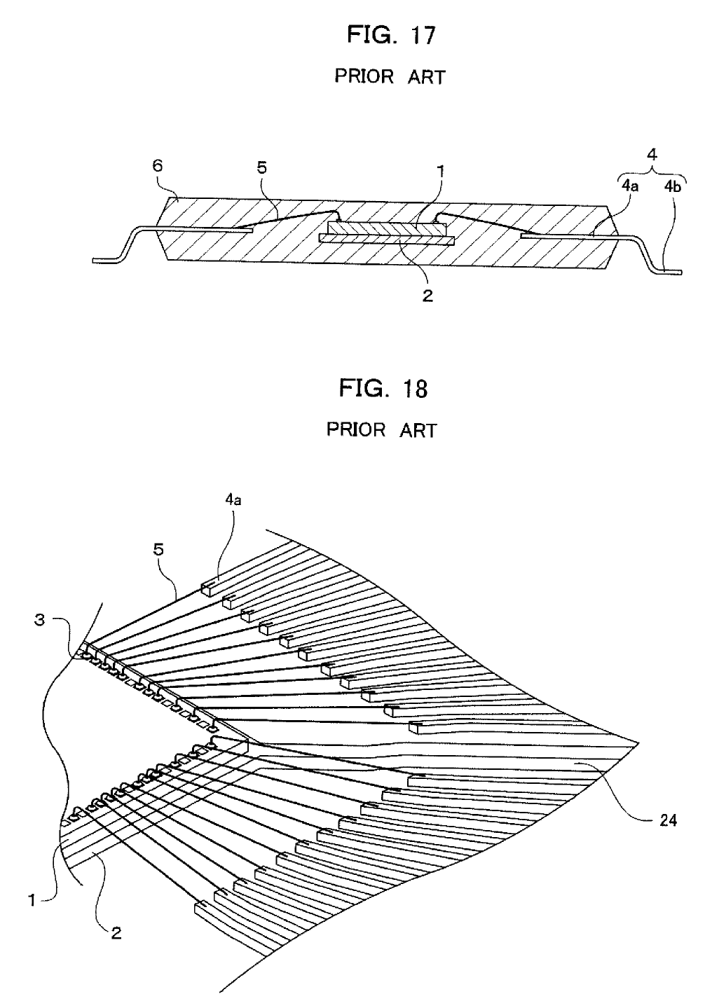

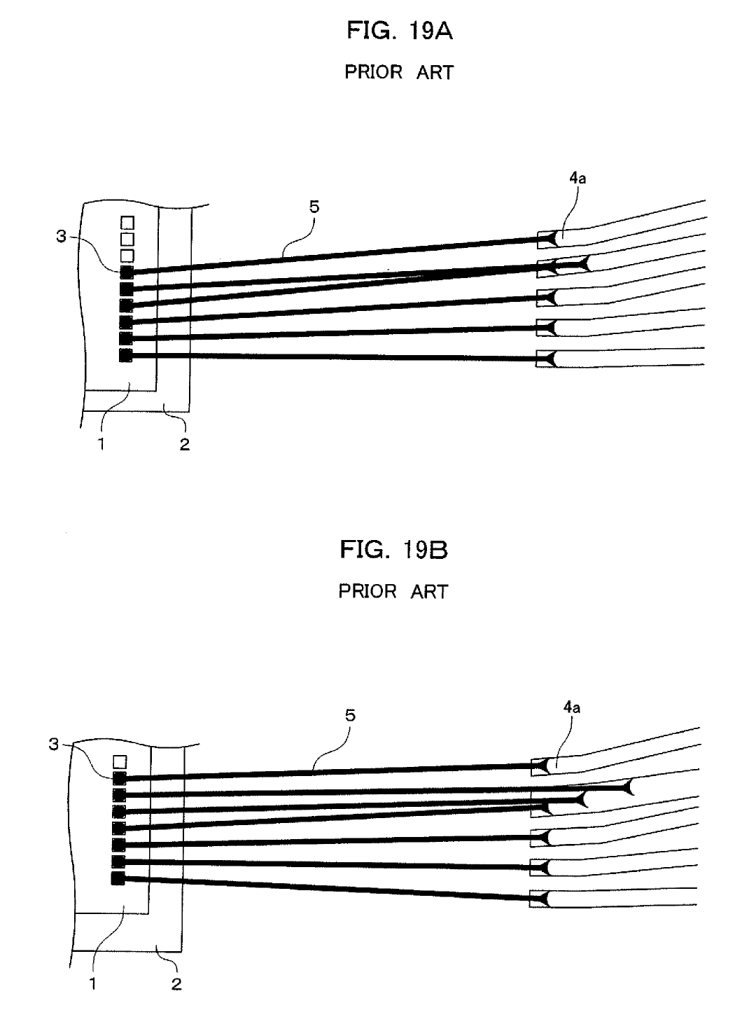

Now, Embodiment 7 of the present invention will be described with reference to the drawings. FIG. 15 is a sectional view of a semiconductor device according to Embodiment 7 of the present invention. FIG. 16A is a top view illustrating the internal structure of a wire bonding portion of the semiconductor device according to Embodiment 7 of the present invention. FIG. 16B is a sectional view illustrating the internal structure of the wire bonding portion of the semiconductor device according to Embodiment 7 of the present invention. However, the same members as those described above in Embodiments 1 to 6 are denoted by the same reference numerals, and the description of these members is omitted.

This semiconductor device is of a QFN (Quad Flat Non-lead Package) type or an SON (Small Outline Non-lead Package) type.

As shown in FIGS. 15, 16A, and 16B, in the semiconductor device, semiconductor chips 1a and 1b with integrated circuits formed thereon are stacked in a vertical direction. The stacked semiconductor chips 1a and 1b are mounted in a die pad portion (chip mounting portion) 25 of a lead frame. Inner leads (leads) 26 from the lead frame are radially arranged around the periphery of the die pad portion 25. The tips of the inner leads 26 are arranged opposite to the die pad portion 25. Wires 5 connect electrodes 3a and 3b, formed on the surfaces of the semiconductor chips 1a and 1b, to the corresponding inner lead (lead) 26. A resin molding member 6 collectively molds a semiconductor chip 1, the die pad portion 25, the wires 5, and the inner leads 26. A bottom surface of each of the inner leads 26 is exposed from a bottom surface of resin molding member 6.

This semiconductor device is different from Embodiment 6, described above, in only that the wiring material is not a wiring board but the lead frame. In Embodiment 7, as shown in FIGS. 15, 16A, and 16B, connection portions at first ends of two wires 5a and 5b are overlappingly connected to the same inner lead (lead) 26. Each of the connection portions is shaped such that the wire is drawn out of almost the center of a protrusion collapsed into a thick coin form as is inherent in a ball bonding method. A second end of the wire 5a is shaped like a thin crescent moon or ellipse as is inherent in a wedge bonding method, and is connected to the electrode 3b on the lower semiconductor chip 1b. A second end of the wire 5b is shaped like a thin crescent moon or ellipse as is inherent in the wedge bonding method, and is connected to the electrode 5a on the upper semiconductor chip 1a.

In this QFN or SON semiconductor device, when the first ends of the plurality of wires are overlappingly connected to the same inner lead (lead), a flat surface may be formed on a bottom surface of a ball as is the case with Embodiment 1 (see FIG. 4). Furthermore, in the second bonding step, a pressurizing tool may be used to press, from immediately above, a part to be subjected to ball bonding, to collapse the part (see FIGS. 5 and 6).

Additionally, in the QFN or SON semiconductor device, as is the case with Embodiment 2, the first ends of the plurality of wires can be overlappingly connected to the same inner lead (lead) by means of a ball bonding method (see FIG. 7).

Additionally, in the QFN or SON semiconductor device, as is the case with Embodiment 3, the second ends of the plurality of wires connected to the same inner lead (lead) can be overlappingly connected to the same electrode on the same semiconductor chip or to the same inner lead (lead) via a bump by means of a wedge bonding method (see FIG. 8).

The QFN or SON semiconductor device has been described. However, also in a resin molding semiconductor device which uses a lead frame such as a QFP semiconductor device or the like having an internal structure similar to that of the QFN or SON semiconductor device, the first ends of the plurality of wires can be overlappingly connected to the same lead by means of the ball bonding method, and the plurality of wires connected to the same lead can be connected to the respective different connection target members or to the same connection target member.

Embodiment 7 can provide the high-quality, inexpensive semiconductor device typified by the QFN, SON, or QFP and using the lead frame as a wiring material, the semiconductor device enabling an easy reduction in the area of the wire connection portion on the lead.

What is claimed is:

1. A method of manufacturing a semiconductor device, the method comprising:
a first bonding step of forming a ball at a tip of a wire projecting from a wire supply device, performing ball bonding to compressively bond the ball to an electrode on a semiconductor chip or a lead or a wiring member located around a periphery of the semiconductor chip, subsequently moving the wire supply device, and performing wedge bonding on a connection target member; and
a second bonding step of forming a ball at a tip of a wire projecting from a wire supply device, performing ball bonding to compress the ball, from immediately above, against a part subjected to the ball bonding in the first bonding step, to bond the ball to the part, subsequently moving the wire supply device, and performing wedge bonding on one of the connection target member in the first bonding step and a different connection target member.

2. The method of manufacturing the semiconductor device according to claim 1, wherein the second bonding step is executed at least twice to connect a plurality of wires to one of the electrode and the lead or to the wiring member.

3. The method of manufacturing the semiconductor device according to claim 2, wherein during the repeated second bonding step, at least one wire is connected to the connection target member in the first bonding step by wedge bonding.

4. The method of manufacturing the semiconductor device according to claim 2, wherein during the repeated second bonding step, at least two wires are connected by wedge bonding to a same connection target member different from the connection target member in the first bonding step.

5. The method of manufacturing a semiconductor device according to claim 1, further comprising a bump forming step of forming a ball at a tip of a wire projecting from a wire supply device and compressively bonding the ball to a part to be subjected to the wedge bonding in the first bonding step and/or the second bonding step, to form a bump, wherein in the first bonding step and/or the second bonding step, the wedge bonding is performed on the bump.

6. A semiconductor device comprising:
a semiconductor chip;
electrodes provided on the semiconductor chip;
a chip mounting portion on which the semiconductor chip is mounted;
leads or wiring members arranged around a periphery of the chip mounting portion;
wires connecting the electrodes on the semiconductor chip to the leads or the wiring members; and
a resin molding member molding at least the semiconductor chip, the chip mounting portion, the wires, and connection portions between the leads or the wiring members and the wires, with resin,
wherein connection portions at first ends of some of the plurality of wires are connected to at least one of the electrodes on the semiconductor chip so that the connection portions overlap, and each of the connection portions is shaped such that the wire is drawn out of almost a center of a protruding portion collapsed into a form of a thick coin as is inherent in a ball bonding method.

7. The semiconductor device according to claim 6, wherein at least some of the plurality of wires with the first ends overlappingly connected to the electrodes on the semiconductor chip each have a second end which is shaped like a thin crescent moon or ellipse as is inherent in a wedge bonding method and which is connected to the same lead or wiring member.

8. The semiconductor device according to claim 6, comprising a plurality of the semiconductor chips, wherein at least some of the plurality of wires with the first ends overlappingly connected to at least one of the electrodes on at least one of the semiconductor chips each have a second end which is shaped like a thin crescent moon or ellipse as is inherent in a wedge bonding method and which is connected to a corresponding electrode on the other semiconductor chip.

9. The semiconductor device according to claim 6, comprising a plurality of the semiconductor chips, wherein some of the plurality of wires with the first ends overlappingly connected to at least one of the electrodes on at least one of the semiconductor chips each have a second end which is shaped like a thin crescent moon or ellipse as is inherent in a wedge bonding method and which is connected to a corresponding electrode on the other semiconductor chip, and some of the plurality of wires each have a second end which is shaped like a thin crescent moon or ellipse as is inherent in the wedge bonding method and which is connected to the lead or the wiring member.

10. The semiconductor device according to claim 6, wherein the chip mounting portion and the lead are constituent members of a lead frame produced by processing a metal plate.

11. The semiconductor device according to claim 6, wherein the chip mounting portion and the wiring member are constituent members of a wiring board.

12. A semiconductor device comprising:
a semiconductor chip;
electrodes provided on the semiconductor chip;
a chip mounting portion on which the semiconductor chip is mounted;
leads or wiring members arranged around a periphery of the chip mounting portion;
wires connecting the electrodes on the semiconductor chip to the leads or the wiring members; and
a resin molding member molding at least the semiconductor chip, the chip mounting portion, the wires, and connection portions between the leads or the wiring members and the wires, with resin,
wherein connection portions at first ends of some of the plurality of wires are overlappingly connected to at least one of the leads or the wiring members, and each of the connection portions is shaped such that the wire is drawn out of almost a center of a protruding portion collapsed into a form of a thick coin as is inherent in a ball bonding method.

13. The semiconductor device according to claim 12, wherein some of the plurality of wires with the first ends overlappingly connected to the lead or the wiring member each have a second end which is shaped like a thin crescent moon or ellipse as is inherent in a wedge bonding method and which is connected to the other lead or wiring member, and some of the plurality of wires each have a second end which is shaped like a thin crescent moon or ellipse as is inherent in a wedge bonding method and which is connected to the corresponding electrode on the semiconductor chip.

14. The semiconductor device according to claim 12, comprising a plurality of the semiconductor chips, wherein at least some of the plurality of wires with the first ends overlappingly connected to the lead or the wiring member each have a second end which is shaped like a thin crescent moon or ellipse as is inherent in a wedge bonding method and which is connected to the electrode on each semiconductor chip.

15. The semiconductor device according to claim 12, wherein the chip mounting portion and the lead are constituent members of a lead frame produced by processing a metal plate.

16. The semiconductor device according to claim 12, wherein the chip mounting portion and the wiring member are constituent members of a wiring board.
